(19) United States
(12) Patent Application Publication
(10) Pub. No.: US 2025/0280552 A1
(43) Pub. Date: Sep. 4, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Motoya KISHIDA, Kanazawa Ishikawa (JP)

(21) Appl. No.: 19/029,549

(22) Filed: Jan. 17, 2025

(30) Foreign Application Priority Data
Mar. 4, 2024 (JP) 2024-032211

(51) Int. Cl. H10D 12/00; H01L 21/768; H10D 12/01; H10D 62/10; H10D 62/83; H10D 64/01; H10D 64/62

(52) U.S. Cl. CPC H10D 12/481; H10D 62/126; H10D 64/62; H01L 21/76897; H10D 12/038; H10D 62/83; H10D 64/01

(57) ABSTRACT

A semiconductor device includes a semiconductor substrate, an interlayer insulating film that is provided on the semiconductor substrate, a first electrode that is provided on the interlayer insulating film, a second electrode that is provided below the semiconductor substrate, a plurality of gate regions extending from the interlayer insulating film in a first direction, which is a thickness direction of the semiconductor substrate, to reach the semiconductor substrate, provided in a second direction intersecting the first direction, and extending in a third direction intersecting the first direction and the second direction, and a plurality of plugs located between the gate regions in the second direction, longer in the second direction than in the third direction, spaced apart from each other in the third direction, and electrically connecting the first electrode to the semiconductor substrate.

### CROSS-REFERENCE TO RELATED APPLICATION(S)

This application is based upon and claims the benefit of priority from Japanese Patent Application No. 2024-032211, filed Mar. 4, 2024, the entire contents of which are incorporated herein by reference.

### FIELD

Embodiments described herein relate generally to a semiconductor device.

### BACKGROUND

A structure is known in which a plug electrically connecting an electrode and a semiconductor substrate opposed to each other via an insulating film is formed. The plug is formed by embedding, for example, W (tungsten) in an opening that is excavated by etching or the like.

### BRIEF DESCRIPTION OF THE DRAWINGS

FIG. 1A is a plan view showing a semiconductor device according to a first embodiment.

FIG. 1B is an enlarged plan view showing a region Ra of the semiconductor device shown in FIG. 1A.

FIG. 2A is a cross-sectional view showing an A-A′ cross section of the semiconductor device shown in FIG. 1B.

FIG. 2B is an enlarged cross-sectional view showing a B-B′ cross section of the semiconductor device shown in FIG. 1B.

FIG. 2C is an enlarged cross-sectional view showing a C-C′ cross section of the semiconductor device shown in FIG. 1B.

FIG. 2D is an enlarged cross-sectional view showing the C-C′ cross section of another configuration of the semiconductor device shown in FIG. 1B.

FIG. 3 is an enlarged plan view showing a first modification of the semiconductor device according to the first embodiment.

FIG. 4 is an enlarged plan view showing a semiconductor device according to a first reference example.

FIG. 5 is a cross-sectional view showing a D-D′ cross section of the semiconductor device shown in FIG. 4.

FIG. 6 is an enlarged plan view showing a semiconductor device according to a second reference example.

FIG. 7 is an enlarged plan view showing a semiconductor device according to a second embodiment.

FIG. 8A is a cross-sectional view showing an E-E′ cross section of the semiconductor device shown in FIG. 7.

FIG. 8B is a cross-sectional view showing an F-F′ cross section of the semiconductor device shown in FIG. 7.

FIG. 9 is an enlarged plan view showing a semiconductor device according to a third embodiment.

FIG. 10 is a cross-sectional view showing a G-G′ cross section of the semiconductor device shown in FIG. 9.

FIGS. 11-16 are each a cross-sectional view corresponding to the A-A′ cross section of the semiconductor device shown in FIG. 1, and illustrate a manufacturing method for the semiconductor device according to the first embodiment.

### DETAILED DESCRIPTION

Embodiments provide a semiconductor device capable of optimizing current control therein and improving electrical characteristics thereof.

In general, according to one embodiment, a semiconductor device includes a semiconductor substrate, an interlayer insulating film that is provided on the semiconductor substrate, a first electrode that is provided on the interlayer insulating film, a second electrode that is provided below the semiconductor substrate, a plurality of gate regions extending from the interlayer insulating film in a first direction, which is a thickness direction of the semiconductor substrate, to reach the semiconductor substrate, provided in a second direction intersecting the first direction, and extending in a third direction intersecting the first direction and the second direction, and a plurality of plugs located between the gate regions in the second direction, longer in the second direction than in the third direction, spaced apart from each other in the third direction, and electrically connecting the first electrode to the semiconductor substrate.

Embodiments of the present disclosure will be described below with reference to the drawings.

The drawings are schematic or conceptual, and a relationship between the thickness and width of each part, a ratio between the sizes of parts, and the like are not necessarily the same as those of the actual ones. Even when the same part is shown, the dimensions and ratios may be different depending on the drawing.

In the present specification and the drawings, elements that are already described with respect to the previous drawings are given the same reference numerals, and detailed descriptions are omitted as appropriate.

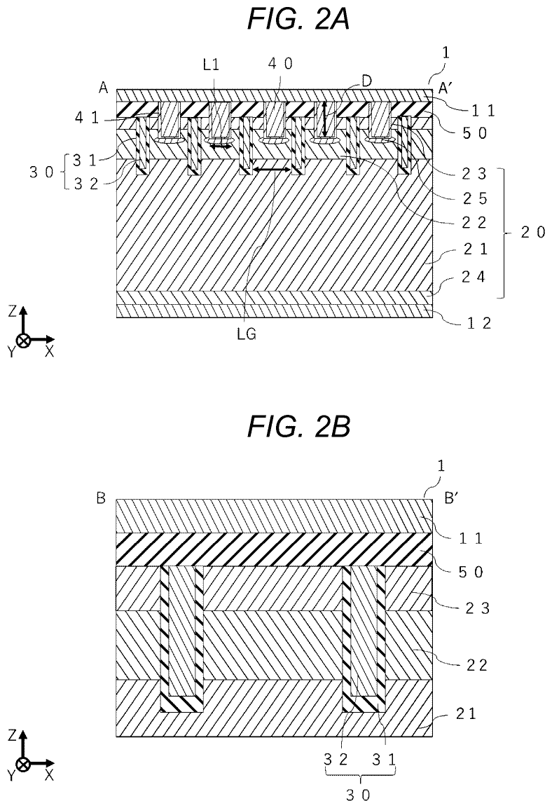

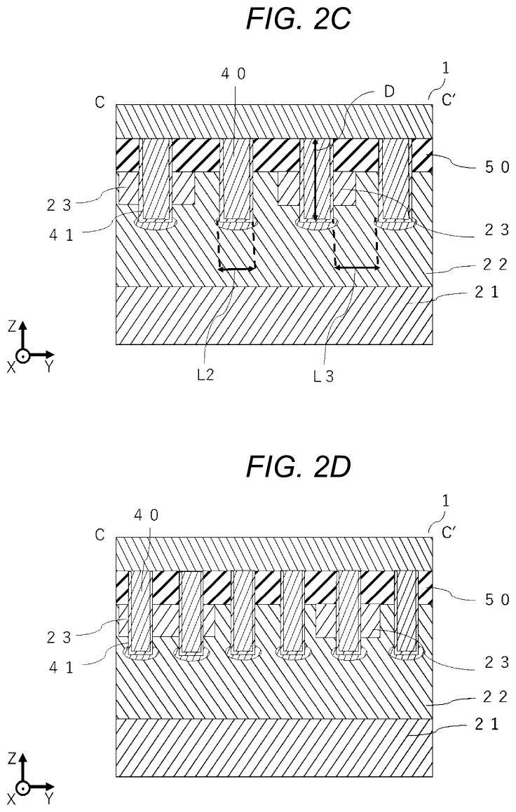

A direction from a first semiconductor region 21 to a second semiconductor region 22 is referred to herein as a Z direction. The Z direction is the thickness direction of a semiconductor substrate 20. In addition, a direction intersecting the Z direction is referred to herein as an X direction, and a direction intersecting the X and Z directions is referred to herein as a Y direction. A semiconductor device 1 shown in FIG. 2 shows a cross-sectional view in an X-Z plane. Although the X, Y, and Z directions are shown in an orthogonal relationship in this embodiment, the directions are not limited to being orthogonal and may be in a mutually intersecting relationship.

In this specification, the positive direction of the Z direction is referred to as “upward”, and the other side is referred to as “downward”. The “upward” and “downward” directions are not limited to the direction of gravity or the direction when the semiconductor device is mounted.

In this specification, technical matters may be described using orthogonal coordinate axes of an X-axis, a Y-axis, and a Z-axis. The orthogonal coordinate axes merely specify relative positions of components, and are not intended to limit the directions recited in the claims to particular directions. For example, the Z-axis is not limited to a height direction with respect to the ground. The +Z-axis direction and the −Z-axis direction are opposite directions. When the Z-axis direction is written without indicating a positive or a negative, it means a direction parallel to the +Z-axis and the −Z-axis.

Further, in the following description, the notations n⁺, n, n⁻, p⁺, p, and p⁻ represent the relative levels of impurity concentrations of respective conductivity types. That is, n⁺ indicates that the impurity concentration of an n-type is relatively higher than that of n, and n⁻ indicates that the impurity concentration of an n-type is relatively lower than that of n. In addition, p⁺ indicates that the impurity concentration of a p-type is relatively higher than that of p, and p⁻ indicates that the impurity concentration of a p-type is relatively lower than that of p. An n⁺-type and an n⁻-type may be simply written as an n-type, and a p⁺-type and a p⁻-type may be simply written as a p-type.

### First Embodiment

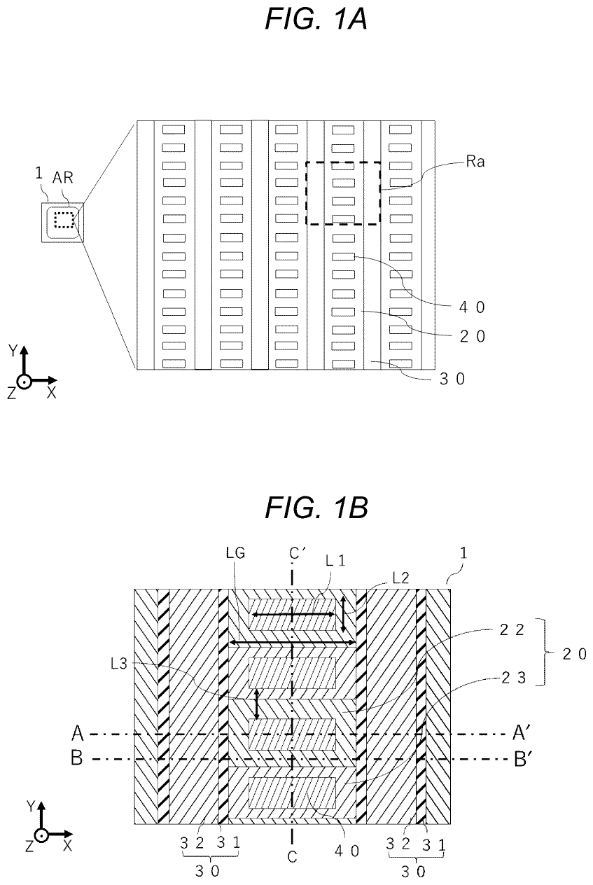

FIG. 1A is a schematic plan view showing an internal wiring structure of the semiconductor device 1 according to this embodiment. FIG. 1B is an enlarged plan view showing a region Ra shown in FIG. 1A. In FIGS. 1A and 1B, a first electrode 11 and an interlayer insulating film 50 are omitted in order to show the internal wiring structure.

FIG. 1A is a schematic top view of the semiconductor device 1 and an enlarged plan view of a portion of the top view. In an active region AR of the semiconductor device 1, for example, an insulated gate bipolar transistor (IGBT) is formed. The active region AR is a region through which a current mainly flows when the semiconductor device 1 is in an ON state.

In the plan view of FIG. 1A, gate regions 30 are repeatedly provided in the X direction on the semiconductor substrate 20 and extend in the Y direction. A plurality of plugs 40 are provided in the semiconductor substrate 20 between the gate regions 30 provided in a plurality of rows in the X direction so as to be spaced apart from each other in the Y direction. Here, it is stated that the plugs 40 are provided between the gate regions 30, but, for example, in a case where the plugs 40 are located on the outermost periphery outside the active region AR of the semiconductor device 1, all of the plugs 40 do not need to be provided between the gate regions 30.

The plan view of FIG. 1A schematically shows a portion of the active region AR, and a peripheral portion of the active region AR is not limited to the structure shown in FIG. 1A. In addition, for example, if an IGBT is formed in the active region AR, a portion where an emitter electrode is formed and a portion where a gate electrode is formed may have different structures.

FIG. 1B is an enlarged plan view of the region Ra shown in FIG. 1A. FIG. 1B shows the internal wiring structure. The gate region 30 includes, for example, a gate insulating film 31 and a gate electrode 32. The gate electrode 32 is covered with the gate insulating film 31. The gate electrodes 32 do not all need to be at the same potential. A dummy electrode may be included in a portion of the gate electrode 32 of the gate region 30. In addition, the gate region 30 does not necessarily need to include the gate electrode 32. A portion of the gate region 30 may be made of, for example, only an insulating material.

The semiconductor substrate 20 includes a first semiconductor region 21 of a first conductivity type (not shown in FIG. 1B), a second semiconductor region 22 of a second conductivity type, and a third semiconductor region 23 of a first conductivity type. The second semiconductor region 22 is, for example, a p-type base region. The third semiconductor region 23 is, for example, an n-type emitter region. The third semiconductor region 23 is selectively provided on the second semiconductor region 22.

As shown in FIG. 1B, a plurality of third semiconductor regions 23 are provided in the Y direction, for example, between the gate regions 30. For example, the length of the third semiconductor region 23 in the X direction is longer than the length thereof in the Y direction. The second semiconductor region 22 is located between the separated third semiconductor regions 23. By providing the plurality of third semiconductor regions 23 in the Y direction, it is possible to control a contact area between the third semiconductor region 23 and the gate region 30 and disperse a flow of a current. As will be described below, when the semiconductor device 1 is in an ON state, a current flows through the third semiconductor region 23 in the vicinity of the gate region 30. The flow of the current in an ON state can be controlled by the arrangement of the plurality of third semiconductor regions 23 formed in the Y direction. The third semiconductor regions 23 may be regions extending in the Y direction and formed continuously.

The plurality of plugs 40 are disposed to be in contact with either one or both of the second semiconductor region 22 or the third semiconductor region 23. A plurality of regions formed in the Y direction may be collectively referred to as the plug 40, but each of the plurality of regions formed may also be referred to as the plug 40.

Lengths L1, L2, L3 and LG shown in FIG. 1B will be described in detail after FIG. 2 is described.

Hereinafter, a cross-sectional structure of the semiconductor device 1 according to the first embodiment will be described with reference to FIGS. 2A, 2B and 2C.

FIGS. 2A, 2B and 2C are cross-sectional views taken along lines A-A′, B-B′ and C-C′ shown in FIG. 1B, respectively. The cross-sectional views of FIGS. 2A, 2B and 2C show the first electrode 11 and the interlayer insulating film 50, which are omitted in FIG. 1B. Further, in the cross-sectional views of FIGS. 2B and 2C, a structure below the first semiconductor region 21 is omitted.

First, the A-A′ cross-sectional view of the semiconductor device 1 according to the first embodiment will be described with reference to FIG. 2A. The semiconductor device 1 according to this embodiment shown in FIG. 2A includes the first electrode 11, a second electrode 12, the semiconductor substrate 20, the gate region 30, the plug 40, and the interlayer insulating film 50. The semiconductor substrate 20 includes the first semiconductor region 21 of a first conductivity type, the second semiconductor region 22 of a second conductivity type, the third semiconductor region 23 of a first conductivity type, a fourth semiconductor region 24 of a second conductivity type, and a fifth semiconductor region 25 of a second conductivity type. The gate region 30 includes a gate insulating film 31 and a gate electrode 32.

The first electrode 11 and the second electrode are, for example, metals containing AlCu or AlSi. The first electrode 11 is, for example, an emitter electrode of an IGBT. The second electrode 12 is, for example, a collector electrode of an IGBT. The semiconductor substrate 20 is provided between the first electrode 11 and the second electrode 12.

The semiconductor substrate 20 is made of, for example, a semiconductor containing Si. The first semiconductor region 21 is, for example, an n-type drift layer. The second semiconductor region 22 is, for example, a p-type base region. The third semiconductor region 23 is, for example, an n⁺-type emitter layer. The fourth semiconductor region 24 is, for example, a p⁺-type collector layer. The fifth semiconductor region 25 is, for example, a p⁺-type contact region. The p-type semiconductor layer is formed, for example, by doping Si substrate with B. The n-type semiconductor layer is formed, for example, by doping Si substrate with N or P.

The gate region 30 is, for example, a gate trench of an IGBT. The gate insulating film 31 contains, for example, silicon oxide such as SiO₂. The gate insulating film 31 is, for example, a gate insulating film of an IGBT and is formed by oxidation. The gate electrode 32 is, for example, a gate electrode of an IGBT, and contains polysilicon.

It is preferable that the plug 40 be made of a metal containing W (tungsten). The plug 40 may also be covered with a barrier metal 41. The barrier metal 41 is formed between the plug 40 and the semiconductor substrate 20 and between the plug 40 and the interlayer insulating film. The barrier metal 41 has a layer structure containing, for example, Ti and TiN. The barrier metal 41 has a higher adhesion to the interlayer insulating film 50 than the plug 40, and prevents the plug 40 from peeling-off from the interlayer insulating film 50 when stress is applied to the semiconductor substrate 20 and the interlayer insulating film 50 due to temperature changes or the like. Further, if the plug 40 is formed on the surface of the barrier metal 41, for example by CVD, the reactivity between a gas used for the CVD and the barrier metal 41 can be controlled by selecting the material of the barrier metal 41. For example, when the CVD is performed using a gas containing fluorine, the reactivity of fluorine can be reduced by the barrier metal 41 containing TiN.

The plug 40 may be covered with the barrier metal 41, and the barrier metal 41 may be in contact with the semiconductor substrate 20. The plug 40 and the semiconductor substrate 20 are electrically connected to each other in a contact portion where the plug 40 and the semiconductor substrate 20 are in contact with each other. In the description of this specification, a contact area between the plug 40 and the semiconductor substrate 20 is described, but the definition of “contact” also includes a case where the plug 40 and the semiconductor substrate 20 face each other via the barrier metal 41.

The plug 40 electrically connects the first electrode 11 and the semiconductor substrate 20. The plug 40 is in contact with the third semiconductor region 23 in the A-A′ cross section and reaches the second semiconductor region 22. The fifth semiconductor region 25 is formed on the bottom surface of the plug 40.

The gate region 30 is provided below the interlayer insulating film 50 and reaches the first semiconductor region 21 in the negative direction of the Z direction. The gate region 30 includes a gate electrode 32 covered with the gate insulating film 31. The gate insulating film 31 is provided between the gate electrode 32 and the semiconductor substrate 20, and at least a portion of the gate insulating film 31 is in contact with the second semiconductor region 22. The gate electrode 32 is electrically insulated from the semiconductor substrate 20 by the gate insulating film 31. By applying a voltage to the gate electrode 32, an inversion layer is formed in the second semiconductor region 22, and the semiconductor device can be set to be in an ON state.

The interlayer insulating film 50 is made of, for example, silicon oxide such as SiO₂. The interlayer insulating film 50 is formed by, for example, CVD. The interlayer insulating film 50 is formed on the semiconductor substrate 20 and is provided to cover the gate region 30. The gate electrode 32 and the first electrode 11 are electrically insulated from each other by the interlayer insulating film 50.

FIG. 2B is an enlarged cross-sectional view taken along a line B-B′ shown in FIG. 1B. Since the B-B′ cross section does not pass through the plug 40, the plug 40 is not shown in FIG. 2B. On the other hand, the gate region 30 extends in the Y direction in FIG. 1B, and thus the gate region 30 is shown in FIG. 2B in the same manner as in FIG. 2A.

FIG. 2C is an enlarged cross-sectional view taken along a line C-C′ shown in FIG. 1B. A plurality of plugs 40 are provided in the Y direction. FIG. 2C also shows a case where a plurality of third semiconductor regions 23 are provided in the Y direction. The arrangement of the plugs 40 in the Y direction can be changed depending on the arrangement of the third semiconductor regions 23 in the Y direction. The plugs 40 and the third semiconductor regions 23 are each provided at a fixed interval in the Y direction, for example.

Some of the plugs 40 may be in contact with the third semiconductor regions 23 and some may be located between the plurality of third semiconductor regions 23. At least one plug 40 is provided between the third semiconductor regions 23 spaced apart in the Y direction. For example, as shown in FIG. 2C, the plugs 40 in contact with the third semiconductor regions 23 and the plugs 40 located between the plurality of third semiconductor regions 23 are alternately repeated in the Y direction. As will be described below with reference to FIG. 2D, the plugs 40 in contact with the third semiconductor regions 23 and the plugs 40 located between the plurality of third semiconductor regions 23 do not have to be alternately repeated in the Y direction. FIG. 2D is a diagram showing an example different from the embodiment shown in FIG. 2C with respect to the cross section in the same direction as in FIG. 2C.

As shown in FIG. 2D, in some of the plurality of plugs 40, the plugs 40 adjacent to each other in the Y direction may be in contact with the third semiconductor region 23. For example, two or more plugs 40 may be in contact with one region among the plurality of third semiconductor regions 23.

Although not shown in FIG. 2D, the plugs 40 adjacent to each other in the Y direction may be in contact with different third semiconductor regions 23 spaced apart from each other in the Y direction among the plurality of third semiconductor regions 23. In other words, the third semiconductor region 23, the second semiconductor region 22, and the third semiconductor region 23 may be arranged in the Y direction between the plugs 40 adjacent to each other in the Y direction.

Alternatively, as shown in FIG. 2D, for at least some of the plurality of plugs 40, the plugs 40 adjacent to each other in the Y direction may be located between the third semiconductor regions 23 that are spaced apart from each other in the Y direction. Two or more plugs 40 may be provided between the third semiconductor regions 23 adjacent to each other in the Y direction among the plurality of third semiconductor regions 23.

The arrangement of the plugs 40 of the semiconductor device 1 according to the first embodiment will be further described below with reference to FIG. 1B and FIGS. 2A, 2B, and 2C.

First, description is given with reference to FIG. 1B. As shown in FIG. 1B, when comparing an interval LG between the gate regions 30 in the X direction and a length L1 of the plug 40 in the X direction, L1 is shorter. By making L1 smaller than LG, the plug 40 can be formed between the gate regions 30. L1 (<LG) cannot necessarily be set to any length smaller than LG, and may be set to be sufficiently smaller than LG in consideration of an error of alignment in the X direction when the plug 40 is formed.

In addition, the length L1 of the plug 40 in the X direction and the length L2 in the Y direction are different from each other. L1 is the length of the long side of the plug 40, for example, having a rectangular cross section in an XY plane, and L2 is the length of the short side of the plug 40, for example, having a rectangular cross section in the XY plane.

An interval L3 between the plugs 40 adjacent to each other in the Y direction may be smaller or larger than L1. The plugs 40 can be provided at a fixed interval L3 as shown in FIG. 1B.

The plug 40 is in contact with the second semiconductor region 22 or the third semiconductor region 23 in the XY plane shown in FIG. 1B. At least a portion of the plug 40 may be in contact with both the second semiconductor region 22 and the third semiconductor region 23 in the XY plane.

Next, description is given with reference to FIG. 2A. The plug 40 has a depth D in the Z direction. The depth D is the length in the Z direction from an interface between the plug 40 and the first electrode 11 to the bottom surface of the plug 40. The shape of the bottom surface of the plug 40 is not limited to that shown in FIG. 2A, and the bottom surface may be rounded.

A ratio between the depth D and the length L1, that is, D/L1, is referred to as a first aspect ratio. In addition, a ratio between the depth D shown in FIG. 2C and the length L2 of the plug 40 in the Y direction, that is, D/L2, is referred to as a second aspect ratio.

The first aspect ratio D/L1 is, for example, within the range of 0<D/L1≤2. If the first aspect ratio satisfies 0<D/L1≤2, the embeddability when forming the plug 40 can be improved. It is preferable that the first aspect ratio be within the range of 0<D/L1≤1.

The second aspect ratio D/L2 satisfies D/L1≤D/L2, for example, 1≤D/L2. By making the second aspect ratio D/L2 satisfy 1≤D/L2, a contact area between the plug 40 and the semiconductor substrate 20 can be increased, which is advantageous for miniaturization. Since the first aspect ratio is smaller than the second aspect ratio, satisfactory embeddability of the plug 40 can be maintained even if the second aspect ratio is large.

For example, the plug 40 may have a structure tapered in the negative direction of the Z direction. In this case, the lengths L1 and L2 may be defined as the maximum length in the X direction of a portion of the plug 40 which is located between the gate regions 30. For example, in the Z direction, the length of the plug 40 in the X direction at a position corresponding to an interface between the semiconductor substrate 20 and the interlayer insulating film 50 is measured and set as L1.

Next, operations of the semiconductor device 1 will be described with reference to FIG. 2A. As an example, operations of an IGBT will be described. Description will be given of an example in which the first electrode 11 is an emitter electrode, the first semiconductor region 21 is an n⁻-type drift region, the second semiconductor region 22 is a p-type base region, the third semiconductor region 23 is an n⁺-type emitter layer, the fourth semiconductor region 24 is a p⁺-type collector layer, and the fifth semiconductor region 25 is a p⁺-type contact region. First, an operation of turning on the IGBT will be described.

A negative voltage is applied to the first electrode 11 with respect to the second electrode 12. By applying a positive voltage to the gate electrode 32 which is equal to or greater than a threshold voltage with respect to the potential of the first electrode 11, an inversion layer (channel) is formed in the second semiconductor region 22 in the vicinity of the gate insulating film 31. That is, an inversion layer with n-type conductivity is formed in the second semiconductor region 22 which is a p-type base region.

The inversion layer formed in the second semiconductor region 22 has the same conductivity type as those of the first semiconductor region 21 and the third semiconductor region 23. Thus, electrons that reach the third semiconductor region 23 from the first electrode 11 (emitter electrode) through the plug 40 flow to the first semiconductor region 21 through the inversion layer formed in the second semiconductor region 22.

Furthermore, holes are injected into the first semiconductor region 21 (drift layer) from the fourth semiconductor region 24 (collector layer) provided below the first semiconductor region 21. In this manner, a current flows from the second electrode 12 (collector electrode) to the first electrode (emitter electrode) with the electrons and the holes as current carriers, and the IGBT is set to be in an ON state.

Next, when the IGBT is turned off, the potential of the gate electrode 32 is set to, for example, the same potential as the first electrode 11. The inversion layer formed in the second semiconductor region 22 is removed, and the injection of electrons from the third semiconductor region 23 to the first semiconductor region 21 is prevented. In order for the IGBT to be completely turned off, it is necessary to discharge carriers accumulated in the first semiconductor region 21 in an ON state. The electrons are discharged to the second electrode 12, and the holes are discharged to the first electrode 11 through the p-type second semiconductor region 22 and the plug 40.

The holes are discharged, for example, through the following route. The holes accumulated in the first semiconductor region 21 are discharged to the plug 40 through the second semiconductor region 22 and the fifth semiconductor region 25 which has the same conductivity type as the second semiconductor region. That is, the fifth semiconductor region 25 connects the plug 40 and the second semiconductor region 22 and is further in ohmic contact with the plug 40 to become a hole discharge route.

That is, the plug 40 is a route for flowing electrons from the first electrode 11 to the third semiconductor region 23 when the IGBT is in an ON state, and discharging holes from the second semiconductor region 22 to the first electrode 11 when the IGBT is turned off. As described above, the plug 40 electrically connects the first electrode 11 and the semiconductor substrate 20, and the semiconductor device 1 operates.

With the semiconductor device 1 of this embodiment, each of the plurality of plugs 40 provided in the Y direction has the length L1 in the X direction and the length L2 in the Y direction different from L1, thereby making it possible to prevent defective formation of the plugs 40 and improve the reliability of the semiconductor device. By improving the flatness of the first electrode 11 formed on the plugs 40, concentration of stress on a portion of the electrode and occurrence of cracks are prevented.

The plug 40 and the semiconductor substrate 20 are generally made of materials having different thermal expansion coefficients. For example, W (tungsten) contained in the plug 40 has a larger thermal expansion coefficient than that of Si (silicon) contained in the semiconductor substrate. When heat is applied, the plug 40 and the semiconductor substrate 20 differ in the degree of expansion, and thus distortion and stress may occur. Stress generated between the plug 40 and the semiconductor substrate 20 may cause warpage in a wafer. In general, as the width of the plug 40 increases, it is necessary to increase the film thickness of W (tungsten), and thus stress is increased, which results in a concern that the warpage of the wafer may become larger. That is, an increase in the size of a contact area between the plug 40 and the semiconductor substrate 20 may result in a concern that stress to be applied to a wafer may be increased.

Hereinafter, as an example, a case where the plug 40 is made of W (tungsten) will be described. The plug 40 is formed, for example, by embedding a conductive material in an opening, which is formed by excavating the semiconductor substrate 20 and the interlayer insulating film 50 in the Z direction. A film containing a conductive material (for example, W) is embedded in the opening by being formed to have a predetermined thickness on the bottom surface and side walls of the opening. For example, in order to form the plug 40 with the length L2 in the Y direction, a film with a thickness of L2/2 is formed on the side walls. In order to fill the opening, a film with a thickness of at least L2/2 is formed on the side walls of the opening. In order to satisfactorily fill the opening without impairing flatness and preventing the formation of voids, a film thickness is preferably L2×(3/5) or more. More preferably, the film thickness is L2×(3/4) or more.

Here, a length Tmax is defined. The length Tmax is a maximum value of a film thickness of W (tungsten) formed on the sidewall of the opening, the film thickness being a length at which the magnitude of stress on the wafer is equal to or less than an allowable predetermined value. The predetermined value allowable for stress is determined such that the amount of wafer warpage caused by the stress is sufficiently small. By setting the film thickness of the W (tungsten) formed on the sidewall of the opening to equal to or less than Tmax, the reliability of the semiconductor device is improved.

In order to prevent the wafer warpage, a necessary thickness L2/2 of the film formed on the sidewall of the opening satisfies L2/2≤Tmax. In other words, L2≤2Tmax. The film with a thickness of L2/2 which is formed on the sidewall of the opening has a film thickness of Tmax or less, and thus the stress on the wafer can be reduced. That is, the length L2 of the plug 40 in the Y direction needs to be set to a length of 2Tmax or less in order to reduce the stress on the wafer.

In order to fill the opening more satisfactorily, it is preferable that L2≤(5/3) Tmax. The film with a thickness of (3/5) L2 which is formed on the side wall of the opening has a film thickness of Tmax or less, and thus the stress on the wafer can be reduced. It is further preferable that L2≤(4/3) Tmax.

For example, the plug 40 is formed such that L2≤(4/3) Tmax, and thus L1 can be arbitrarily increased within a range without exceeding LG. This is because the W (tungsten) film is formed to be thin in the Y direction in order to prevent wafer warpage. Furthermore, the opening can be filled satisfactorily by preventing the formation of voids. In other words, it is possible to prevent defective formation of the plug 40.

Since L1 may be determined without considering the influence of the film thickness of W on the wafer warpage, the length of a region where the plug 40 is in contact with the second semiconductor region 22 or the third semiconductor region 23 can be increased in the X direction to increase a contact area. Thus, on-resistance is reduced, and the discharge of carriers from the semiconductor substrate 20 to the plug 40 is promoted during switching, whereby a switching loss can be reduced. By reducing a switching loss, power consumption is reduced, and it is possible to provide the semiconductor device with improved switching performance.

Since L1 may be determined without considering the influence of the film thickness of W on the wafer warpage, according to this embodiment, the plug 40 with satisfactory embeddability can be formed when the range of the value of the interval LG between the gate regions 30 in the X direction is wide. The wide range of the value of the interval LG will be described below in comparison with first and second reference examples.

In addition, according to this embodiment, the plurality of third semiconductor regions 23 are provided in the Y direction, and plugs may be formed in contact with the third semiconductor regions 23, or plugs 40 may be formed in contact with the second semiconductor region 22 between the third semiconductor regions 23 spaced apart from each other in the Y direction. A current density in the XY plane can also be controlled by changing either a layout of the third semiconductor region 23 or a layout of the plugs 40. By increasing the degree of freedom in design and controlling the amount of heat generated by a current, the reliability of the semiconductor device can be improved.

The third semiconductor region 23 is a region serving as a path for a current when the semiconductor device 1 is in an ON state. The shorter a distance between the plurality of plugs 40 in contact with the third semiconductor region 23 becomes, in other words, as the degree of dispersion of the plurality of plugs 40 in contact with the third semiconductor region 23 in the XY plane becomes lower, the higher the current density in an ON state. In contrast, by increasing the degree of dispersion of the plurality of plugs 40 in contact with the third semiconductor region 23 in the XY plane, it is possible to reduce the current density and reduce the amount of heat locally generated.

For example, the plugs 40 adjacent to each other in the Y direction may be located between the third semiconductor regions 23 that are spaced apart from each other in the Y direction. That is, it is possible to reduce the current density and the amount of heat generated by increasing the proportion of the plugs 40 in contact with the second semiconductor region 22. Furthermore, a wide carrier discharge path can be formed by increasing a contact area between the second semiconductor region 22 and the plugs 40, thereby reducing a switching loss.

After the amount of heat generated is reduced, for example, the plugs 40 adjacent to each other in the Y direction can be allowed to be in contact with the third semiconductor region 23 at a portion, thereby increasing the current density. In a region with a relatively high heat dissipation, the current density can be designed to be high.

In addition, some of the plugs 40 may be provided to straddle the second semiconductor region 22 and the third semiconductor region 23 in the Y direction. By changing a positional relationship between the third semiconductor region 23 and the plugs 40, the degree of dispersion of the plurality of plugs 40 in contact with the third semiconductor region 23 in the XY plane can be adjusted. That is, by adjusting the arrangement of the third semiconductor regions 23 and the arrangement of the plugs 40, the amount of heat generated and the current density can be optimized in accordance with the electrical characteristics of the semiconductor device.

The degree of dispersion of the plurality of plugs 40 in contact with the third semiconductor region 23 in the XY plane can be changed in the XY plane. For example, the degree of dispersion may be increased toward the end of the active region AR shown in FIG. 1. It is possible to reduce the amount of heat generated at the end of the active region AR and improve reliability.

According to this embodiment, it is possible to control the current density in the XY plane by the layout of the plugs 40 without necessarily changing the layout of the third semiconductor region 23. The degree of freedom in design for controlling the current density is improved. Furthermore, it is possible to reduce the current density by locally changing a positional relationship between the third semiconductor region 23 and the plugs 40 in a region in the XY plane where the amount of heat generated is desired to be reduced. At the same time, the layout of the third semiconductor region 23 can be changed to adjust the layout of the third semiconductor region 23 and the layout of the plugs 40, thereby further increasing the degree of freedom in design.

Furthermore, as compared to a case where a current is controlled by changing only the layout of the third semiconductor region 23, it is possible to expand the range of selection according to the arrangement of the plugs 40 for a predetermined layout of the third semiconductor region 23. By appropriately selecting the arrangement of the plugs 40, the electrical characteristics of the semiconductor device can be improved. That is, current flow can be further controlled by the arrangement of the plugs 40 in the X and Y directions, in addition to the layout of the third semiconductor region 23.

### Modification of First Embodiment

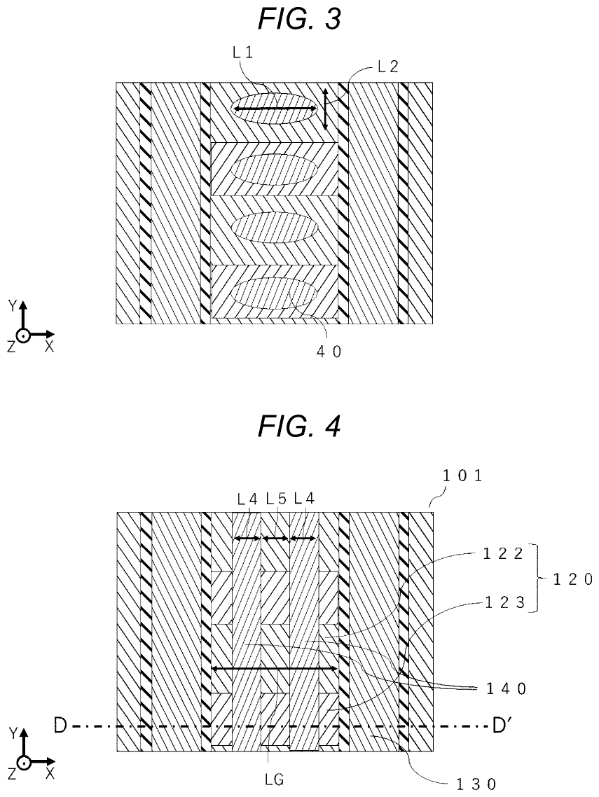

Next, the semiconductor device 1 according to a modification of the first embodiment will be described with reference to FIG. 3. FIG. 3 is an enlarged plan view of the semiconductor device 1 according to the modification of the first embodiment. A difference between FIG. 3 and FIG. 1B is in a cross-sectional shape of the plug 40 in the XY plane. FIG. 3 shows a case where the plug 40 has an elliptical shape having a length L1 in the X direction and a length L2 in the Y direction. The length L1 in the X direction is the length of the major axis of the ellipse, and the length L2 in the Y direction is the length of the minor axis of the ellipse. For example, L2<L1, and L2≤2Tmax. A relationship of L2≤(5/3) Tmax or L2≤(4/3) Tmax may be established.

In addition, the cross-sectional shape of the plug 40 in the XY plane is not limited to the rectangular shape shown in FIG. 1B or the elliptical shape shown in FIG. 3. For example, the cross-sectional shape may be an oval shape or a polygonal shape, or may be a polygonal shape with rounded corners.

More generally, any point inside a figure (for example, a rectangle) representing the cross-sectional shape of the plug 40 in the XY plane may be located within a distance of, for example, Tmax from at least one point on the outer periphery of the figure. The cross-sectional shape of the plug 40 in the XY plane in at least one direction has a length of 2Tmax or less. When the plug 40 is formed, the opening can be satisfactorily filled with W (tungsten) having a film thickness of Tmax or less.

For example, in the elliptical shape shown in FIG. 3, the length of the minor axis L2≤2Tmax. A distance between the center of the ellipse and a point on the circumference of the ellipse in both directions in the Y direction (minor axis direction) is equal to or less than Tmax. That is, the center of the ellipse can be satisfactorily filled with a tungsten film having a film thickness of Tmax or less from the sidewall of the opening. The same is true of any point inside the ellipse, which is the cross-sectional shape of the plug 40 shown in FIG. 3.

In addition, the cross-sectional shape of the plug 40 in the XY plane may be curved and may be, for example, an L-shape. Alternatively, the cross-sectional shape may be a cruciform.

That is, the shape of the plug 40 is not limited to an elliptical shape, but may be any shape that can prevent defective formation of the plug 40. A figure with long and short sides, such as a rectangle, is preferable because it is possible to prevent defective formation of the plug 40 on the short side and take up a large length of a region where the plug 40 and the semiconductor substrate 20 are in contact with each other on the long side. In this specification, a shape with long and short sides is defined as a “rectangle.”

The present disclosure is not limited to the semiconductor device 1 according to the first embodiment shown in FIG. 1B, and it is possible to prevent defective formation of the plug 40 and improve the reliability of the semiconductor device by, for example, the modification of the first embodiment shown in FIG. 3. At the same time, it is possible to reduce a switching loss and improve the switching performance of the semiconductor device by taking a wide contact area between the plug 40 and the second semiconductor region 22. The modification of the first embodiment is described above.

### First Reference Example

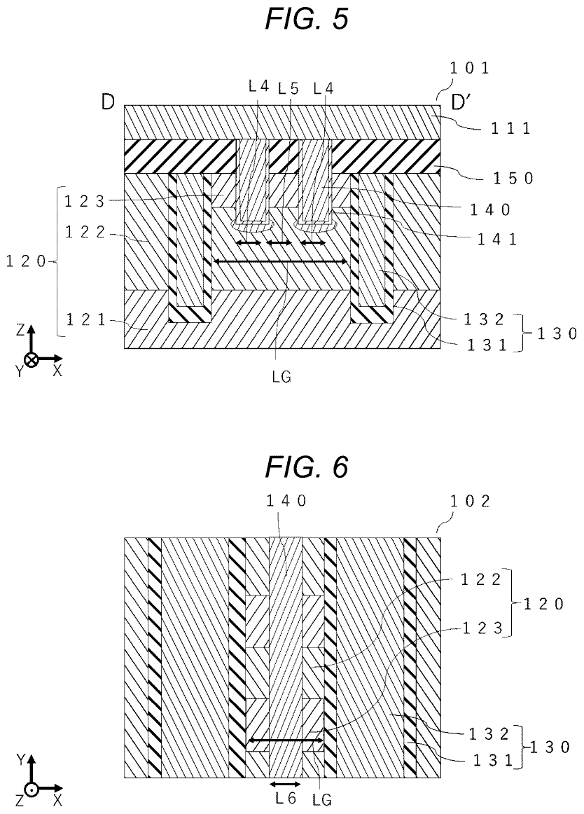

Next, a semiconductor device 101 according to a first reference example will be described with reference to FIGS. 4 and 5. Differences from the first embodiment will be described in detail. FIGS. 4 and 5 are an enlarged plan view and a cross-sectional view of the semiconductor device 101 according to the first reference example, respectively. FIG. 4 is an enlarged plan view showing an internal wiring structure, and FIG. 5 is a cross-sectional view showing a D-D′ cross section of the semiconductor device shown in FIG. 4.

First, a plan view of the first reference example will be described with reference to FIG. 4. In the semiconductor device 101, plugs 140 are provided in two rows in the X direction and extend in the Y direction. The plurality of plugs 140 are provided between a plurality of gate regions 130 provided in the X direction and extending in the Y direction. The plugs 140 are in contact with a second semiconductor region 122 and a third semiconductor region 123 of a semiconductor substrate 120.

The gate region 130 includes a gate electrode 132 and a gate insulating film 131 that covers the gate electrode 132. The gate electrode 132 and the gate insulating film 131 extend in the Y direction. The gate electrode 132 is electrically insulated from the semiconductor substrate 120.

The second semiconductor region 122 and the third semiconductor region 123 are semiconductor regions having different conductivity types. For example, the second semiconductor region 122 is a p-type base region, and the third semiconductor region 123 is an n-type emitter region.

The width in the X direction of the plug 140 in the semiconductor device 101 according to the first reference example is referred to as L4, and an interval in the X direction between the plugs 140 arranged in two rows in the X direction is referred to as L5. In addition, an interval in the X direction between the gate regions 130 adjacent to each other in the X direction is referred to as LG.

Next, a D-D′ cross-sectional view of the semiconductor device 101 according to the first reference example will be described with reference to FIG. 5. The plug 140 is provided from a first electrode 111 to the semiconductor substrate 120 through an interlayer insulating film 150. In the D-D′ cross section shown in FIG. 5, the plug 140 is in contact with the third semiconductor region 123.

The gate region 130 is filled with the gate electrode 132 and the gate insulating film 131 that covers the gate electrode 132. The gate insulating film 131 reaches a first semiconductor region 121 of the semiconductor substrate 120. The gate insulating film 131 is in contact with the second semiconductor region 122.

In FIGS. 4 and 5, 2L4+L5≤LG, and two rows of plugs 140 are provided in the X direction. If 2L4+L5>LG, two rows of plugs 140 cannot be formed between the gate regions 130. In other words, an opening for embedding two rows of plugs 140 cannot be formed between the gate regions 130.

The opening is formed by excavating the semiconductor substrate 120 and the interlayer insulating film 150 in order to embed the plugs 140. The plugs 140 are formed by forming a W (tungsten) film in the opening. In order to form the plugs 140 shown in FIG. 5, it is necessary to form two rows of openings with a width of L4 in the X direction at an interval of L5 in the X direction.

In general, L4 cannot be made infinitely small. L4 cannot be set to be equal to or less than a length Lmin which is determined from the precision of excavation of the semiconductor substrate, and L4≥Lmin. When an opening for embedding W (tungsten) is formed, there is a limit to the processing accuracy for excavating the semiconductor substrate 120 and the interlayer insulating film 150. That is, the processing accuracy in the excavation process may determine the minimum value of L4 that can be realized. In this manner, the length Lmin can be defined as the minimum value of L4 determined by the constraints of the processing accuracy. That is, Lmin can be defined as the minimum diameter of the opening to be provided in the semiconductor substrate.

Similarly, L5 also has a limit due to the processing accuracy, and the minimum value of L5 that can be realized can also be determined by the processing accuracy. For example, the inequality L5≥Lmin holds because the processing accuracy for forming the opening by excavation and the processing accuracy for forming a region (mesa portion) that remains unexcavated are substantially the same. Hereinafter, a discussion will be made assuming that both the minimum values of L4 and L5 are Lmin.

If LG<3Lmin, 2L4+L5 (≥3Lmin)>LG holds due to the limit of the processing accuracy at the forming the opening, so it is difficult to form two rows of plugs 140 in the X direction as shown in FIGS. 4 and 5. That is, with the semiconductor device 101 of the first reference example, If LG<3Lmin, it is difficult to form the plugs 140.

In addition, according to the first reference example, If LG is large, it may not be possible to increase the length in the X direction of the region where the plugs 140 and the semiconductor substrate 120 are in contact with each other. This is because, if L4>2Tmax, a thickness of at least Tmax or more is required as the film thickness of W in order to avoid the generation of voids, which increases stress on the wafer and promotes wafer warpage. In order to secure the reliability of the semiconductor device, it is preferable to set the length L4 to be in the range of L4≤2Tmax. In order to secure flatness, it is preferable to set the length to be in the range of L4≤(4/3) Tmax. For simplicity, the case of L4≤2Tmax will be described below, but the same is true of the cases of L4≤(5/3) Tmax and L4≤(4/3) Tmax.

If two rows of plugs 140 are formed in the X direction and the reliability of the semiconductor device is secured, the length in the X direction of the region where the plugs 140 and the semiconductor substrate 120 are in contact with each other cannot be greater than 4Tmax. That is, the length L4 cannot necessarily be set to be large in proportion to the interval LG between the gate regions 130 in the X direction, and it is difficult to increase a contact area between the plugs 140 and the semiconductor substrate 120 in accordance with the value of LG.

Specifically, If the range of the value of LG is 4Tmax+Lmin<LG, it becomes difficult to increase the contact area between the plug 140 and the semiconductor substrate 120 in the first reference example. This is because L5 requires a minimum length of Lmin, and even if the value of LG is increased beyond 4Tmax+Lmin, each of the two rows of plugs 140 can only have a maximum width of 2Tmax.

In order to prevent an increase in stress and wafer warpage if LG is increased in the range of LG>4Tmax+Lmin, L4 is limited to a length that satisfies L4≤2Tmax, and the length of a portion that does not form the plug 140 (the length of L5 or the length in the X direction between the plug 140 and the gate region 130) is increased. Thus, it is difficult to increase the contact area between the plugs 140 and the semiconductor substrate 120 in accordance with the value of LG. Since it is difficult to increase the contact area between the plugs 140 and the semiconductor substrate 120, it is difficult to promote the discharge of carriers in a turn-off state.

In summary, with the semiconductor device 101 of the first reference example, if LG<3Lmin, it is difficult to form the plugs 140 between the gate regions 130. In addition, if 4Tmax+Lmin<LG, it is difficult to increase the contact area between the plugs 140 and the semiconductor substrate 120 as LG increases beyond 4Tmax+Lmin. That is, it can be said that the structure in the first reference example is suitable only for LG within the range of 3Lmin≤LG≤4Tmax+Lmin.

On the other hand, with the semiconductor device 1 of the first embodiment, the plugs 40 can be formed regardless of the interval LG between the gate region 30 in the X direction. In particular, even if (Lmin<) LG<3Lmin, the plugs 40 can be formed in the semiconductor device 1.

Furthermore, with the semiconductor device 1 of the first embodiment, if LG is large, L1 can also be increased in proportion to LG, and the contact area between the plugs 40 and the semiconductor substrate 20 can be increased in accordance with the value of LG. According to the semiconductor device 1 of the first embodiment, it is possible to increase the contact area between the plugs 40 and the semiconductor substrate 20 in accordance with LG, even in the range of 4Tmax+Lmin<LG, in which it becomes difficult in the first reference example to increase the contact area between the plugs 140 and the semiconductor substrate 20. Thus, it is possible to promote the discharge of carriers in a turn-off state and reduce a switching loss.

With the semiconductor device 1 of the first embodiment, it is possible to improve the reliability and performance of the semiconductor device for a wider range of LG than in the first reference example, that is, for more diversified arrangement of the gate regions 30.

### Second Reference Example

Next, a semiconductor device 102 according to a second reference example will be described with reference to FIG. 6.

FIG. 6 is an enlarged plan view showing the semiconductor device 102 according to the second reference example. The semiconductor device 102 according to the second reference example is different from the semiconductor device 101 according to the first reference example in that the plugs 140 are provided in a row in the X direction and extend in the Y direction. The width in the X direction of the plugs 140 provided in a row in the X direction is referred to as L6. As in the first reference example, an interval between the gate regions 130 in the X direction is referred to as LG.

With the semiconductor device 102 of the second reference example, it is possible to form the plugs 140 if L6 is smaller than or equal to LG. In other words, using a length Lmin determined by the accuracy of excavation for the length L6, it is possible to form the plugs 140 if LG≥ Lmin.

On the other hand, if L6>2Tmax, it is difficult to prevent defective formation of the plugs 140 while preventing wafer warpage. That is, in order to secure the reliability of the semiconductor device, it is preferable that L6 have a length that satisfies L6≤2Tmax.

In the semiconductor device 102 according to the second reference example, it is necessary to form the plugs 140 in a range that satisfies L6≤2Tmax in order not to impair the reliability of the semiconductor device. As LG increases in the range of LG>2Tmax, it becomes difficult to increase a contact area between the plugs 140 and the semiconductor substrate 120 in accordance with LG.

In summary, with the semiconductor device 102 of the second reference example, only for LG within the range of Lmin≤LG≤2Tmax, the contact area between the plugs 140 and the semiconductor substrate 120 can be increased to promote the discharge of carriers and improve the performance of the semiconductor device.

On the other hand, with the semiconductor device 1 of the first embodiment, L1 is set to be large in accordance with LG, and thus the contact area between the plugs 40 and the semiconductor substrate 20 can be increased even for LG in the range of 2Tmax<LG to promote the discharge of carriers and improve the switching performance of the semiconductor device.

The semiconductor device 102 according to the second reference example is described above.

Next, the semiconductor device 101 according to the first reference example and the semiconductor device 102 according to the second reference example will be described in comparison with the semiconductor device 1 according to the first embodiment. To summarize, the second reference example is not suitable if LG is in the range of LG<Lmin or 2Tmax<LG, and the first reference example is not suitable if LG is in the range of LG<3Lmin or 4Tmax+Lmin<LG. Combining these two inequalities and assuming 2Tmax<3Lmin for simplicity, if LG is set to be in the range of LG<Lmin (from the second reference example), 2Tmax<LG<3Lmin (2Tmax<LG from the second reference example and LG<3Lmin from the first reference example) or 4Tmax+Lmin<LG (from the first reference example), neither the structure in the first reference example nor the structure in the second reference example is suitable.

On the other hand, in the semiconductor device 1 according to the first embodiment, the contact area between the plugs 140 and the semiconductor substrate 20 can be increased for any value of LG greater than Lmin.

In both the semiconductor device 101 according to the first reference example and the semiconductor device 102 according to the second reference example, it becomes difficult to improve the performance if the interval LG between the gate regions 130 in the X direction is within a specific range.

That is, depending on the value of LG, it is necessary to select each time which of the semiconductor device 101 according to the first reference example or the semiconductor device 102 according to the second reference example is applied. Furthermore, there is a problem that there is a range of LG (2Tmax<LG<3Lmin or 4Tmax+Lmin<LG) in which the plugs 140 cannot be efficiently formed with any of the semiconductor device 101 according to the first reference example or the semiconductor device 102 according to the second reference example.

Here, “efficiently forming the plugs 140” means that it is possible to increase the contact area between the plugs 140 and the semiconductor substrate 20 in accordance with LG as LG increases. In contrast, when it is difficult to increase the contact area between the plugs 140 and the semiconductor substrate 20 in response to an increase in LG, it can be said that the plugs 140 cannot be efficiently formed.

The length LG may be determined by the configuration of the semiconductor device. For example, an interval between gate regions of an IGBT may be determined based on characteristics required for the semiconductor device, such as a breakdown voltage. Thus, LG cannot necessarily be selected arbitrarily, and there may be cases where a gate region 30 has to be formed such that LG has a value within the range of 2Tmax<LG<3Lmin or 4Tmax+Lmin<LG.

If the LG value required for the semiconductor device is within the range of 2Tmax<LG<3Lmin or 4Tmax+Lmin<LG, neither the first nor the second reference example is appropriate. That is, neither the first nor the second reference example can efficiently form the plug 140.

Furthermore, for example, when focusing on the range of the value of LG, that is, 3Lmin≤LG≤4Tmax+Lmin, for which it can be determined that the first reference example is suitable, the range of the value of LG satisfying the inequality is limited as a difference between 2Tmax and Lmin becomes smaller. That is, if 2Tmax and Lmin become substantially the same length, the range of LG for which the structure in the first reference example is suitable becomes narrower. The same is true of the range of the value of LG for which the second reference example is suitable, that is, Lmin<LG<2Tmax.

That is, for example, the more it becomes necessary to reduce the film thickness of a tungsten film by reducing stress on a wafer, the more limited the range of the value of LG for efficiently forming the plugs 140 becomes according to the first and second reference examples. As the range of the value of LG becomes more limited, the degree of freedom in designing the semiconductor device decreases.

The inequality for LG is described above. On the other hand, it may be necessary to consider the inequality for L1 as well. The inequality for L1 can be considered when L1 is set to be smaller than LG by a certain value as a measure to deal with an error of alignment in the X direction at the time of forming the plugs 40. That is, in reality, L1 is not necessarily set to a length equal to LG (even if LG>Lmin, the plug 40 cannot necessarily be formed), and it may be appropriate to consider an inequality for the length L1.

For example, if Lmin<LG, the plug 40 shown in FIG. 1B cannot be necessarily formed. This is because there is a concern that the plug 40 and the gate electrode 32 will be electrically connected due to an error of alignment in the X direction at the time of forming the plug 40 having L1 which is a length equal to LG. Consequently, it is considered that L1 is set to be smaller than LG by the error of the alignment so that the plug 40 and the gate electrode 32 are not electrically connected. In this case, even if Lmin<LG, there is a concern that L1<Lmin, which eliminates realizability in consideration of the accuracy of excavation.

On the other hand, if Lmin<L1, the plug 40 shown in FIG. 1B can be formed from the viewpoint of the accuracy of excavation. That is, considering an error of alignment, Lmin<LG and Lmin<L1 do not necessarily have the same meaning. Thus, it is preferable to consider the inequality for LG and the inequality for L1.

In the semiconductor device 1 according to the first embodiment shown in FIG. 3, the inequality for LG can be rephrased as the inequality for L1. For example, the inequality 2Tmax<LG<3Lmin can be rephrased as an inequality for L1 (2Tmax<L1<3Lmin). When the inequality for LG is rephrased as the inequality for L1, the semiconductor device 1 according to the first embodiment can form the plug 40 even if 2Tmax<L1<3Lmin or 4Tmax+Lmin<L1 (<5Lmin).

Hereinafter, more generally, a case where n rows (n is a natural number) of plugs 140 are formed in the X direction between the gate regions 130 (not shown) will be described. The first reference example corresponds to a case where n=2, and the second reference example corresponds to a case where n=1.

For example, if n=3, three rows of plugs 140 with a width of L4 are formed in the X direction, and the semiconductor substrate 20 with a width of L5 is provided between the plugs 140. Thus, since a relationship of 3L4+2L5≤LG has to be satisfied, and Lmin≤L4 and Lmin≤L5, a relationship of 5Lmin≤LG needs to be satisfied to form three rows of plugs 140. If three rows of plugs 140 are formed in the X direction, it becomes difficult to form three rows of plugs 140 in the X direction for LG in the range of LG<5Lmin.

In addition, if n=3 and 6Tmax+2Lmin<LG, it becomes difficult to increase a contact area between the plugs 140 and the semiconductor substrate 20 in proportion to LG, that is, to form the plugs 140 efficiently. In other words, if n=3, the plugs 140 can be formed efficiently only within the range of 5Lmin≤LG≤6Tmax+2Lmin.

Thus, the range of the value of LG (4Tmax+Lmin<LG<5Lmin) exists between the range of the value of LG for which the second reference example (n=2) is appropriate, that is, 3Lmin≤LG≤4Tmax+Lmin, and the range of the value of LG for which an example of n=3 is appropriate.

By a similar discussion, in general, if n rows of plugs 140 (n is a natural number) are formed in the X direction between the gate regions 130, the plugs 140 cannot be formed efficiently unless (2n−1)× Lmin≤LG≤n×2Tmax+ (n−1)×Lmin.

As described above, in the case of LG in the range of 2Tmax<LG<3Lmin, the plugs 140 cannot be formed efficiently by either the second reference example (n=1) or the first reference example (n=2). Similarly, when LG is in the range of an inequality of n×2Tmax+ (n−1)×Lmin<LG< (2n+1)×Lmin for a certain natural number n, it is difficult to efficiently form the n rows of plugs 140 in the X direction.

That is, in a method of forming the n rows of plugs 140 in the X direction, manufacturing costs may increase due to changing the number of rows of plugs 140 formed in the X direction depending on the value of LG.

Furthermore, as is apparent from an inequality of (2n−1)×Lmin<LG<n×2Tmax+ (n−1)×Lmin, for any natural number n, the range of the value of LG for which it is appropriate to form n rows of plugs 140 becomes narrow if the film thickness of the tungsten film has to be reduced for reducing stress on the wafer.

On the other hand, with the semiconductor device 1 of the first embodiment, L1 can be set to be large in accordance with LG regardless of the value of LG, and thus a contact area between the plugs 40 and the semiconductor substrate 20 can be increased. That is, the plugs 40 can be formed efficiently for a wider range of the value of LG. Specifically, even if LG is within the range of the inequality n×2Tmax+ (n−1)×Lmin<LG< (2n+1)× Lmin for a certain natural number n, the plugs 40 can be formed efficiently. Thus, the degree of freedom in designing the semiconductor device is increased as compared to a method of forming n rows of plugs 140 in the X direction.

With the semiconductor device 1 of the first embodiment, it is possible to efficiently form the plugs 40 even if the range of the value of LG is wider. For example, even if the value of LG is restricted due to the electrical characteristics of the semiconductor device, the plugs 40 can be efficiently formed. By increasing the range of selection of the value of LG, it is possible to increase the range of selection according to optimization of current control, for example, when the magnitude and distribution of a current flowing through the semiconductor device are controlled in accordance with the arrangement of the gate region 30. It is possible to improve the electrical characteristics by appropriately selecting the value of LG.

### Second Embodiment

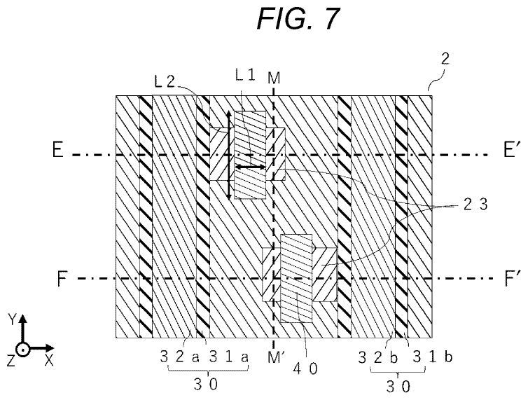

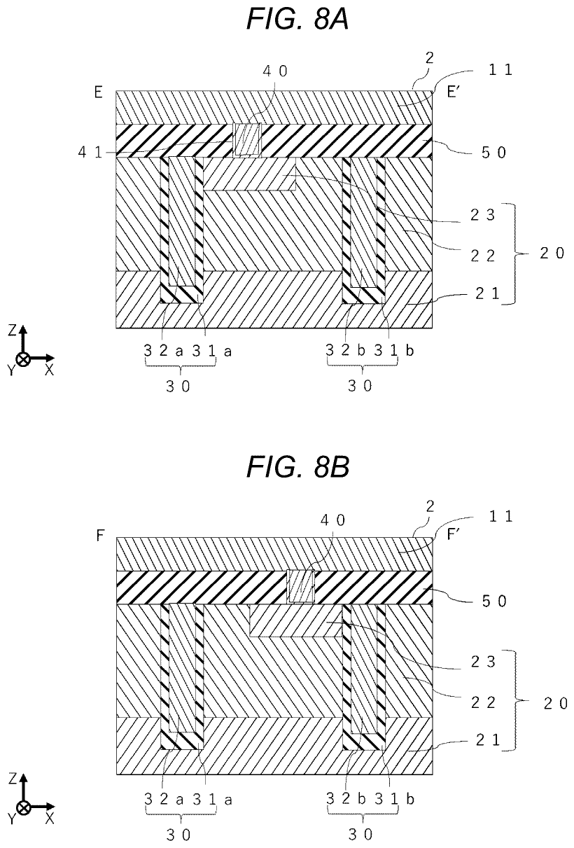

Next, a semiconductor device 2 according to a second embodiment will be described with reference to FIG. 7 and FIGS. 8A and 8B. The semiconductor device 2 according to the second embodiment is an example of a structure that can be implemented by increasing the degree of freedom in designing a third semiconductor region 23 and a plug 40.

FIG. 7 and FIGS. 8A and 8B are an enlarged plan view and cross-sectional views showing the semiconductor device 2 according to the second embodiment, respectively. FIG. 7 is an enlarged plan view, FIG. 8A shows an E-E′ cross section of the semiconductor device shown in FIG. 7, and FIG. 8B shows an F-F′ cross section of the semiconductor device shown in FIG. 7. In FIG. 7, description of portions in common with those in FIG. 1B is omitted. In FIGS. 8A and 8B, description of portions in common with those in FIG. 2A is omitted.

The semiconductor device 2 according to the second embodiment shown in FIG. 7 includes third semiconductor regions 23 disposed between a plurality of gate regions 30 provided in the X direction, the third semiconductor regions 23 being offset with respect to each other in the X direction and the Y direction. That is, the plurality of third semiconductor regions 23 are provided in the Y direction, and at least one set of third semiconductor regions 23 among the plurality of third semiconductor regions 23 are disposed to be offset with respect to each other in the X direction, which means that at least one of the third semiconductor regions 23 is located in the positive direction of the X direction between the gate regions 30, and at least one of the third semiconductor regions 23 is located in the negative direction of the X direction between the gate regions 30. In other words, the third semiconductor regions 23 are not aligned in the Y direction.

Here, the expression “the third semiconductor region 23 is located in the positive (negative) direction of the X direction between the gate regions 30” means that the center of each of the plurality of third semiconductor regions 23 is located in the positive (negative) direction of the X direction with respect to a median line MM′ connecting points at equal distances from two gate regions 30 adjacent to each other in the X direction. Among the third semiconductor regions 23 located in the positive direction of the X direction, an end in the negative direction of the X direction may be located in the negative direction of the X direction from the median line MM′ as in the example shown in FIG. 7. According to this embodiment, it is possible to achieve a satisfactory contact by the plurality of plugs 40 provided in the Y direction even when the end of the third semiconductor region 23 in the negative direction of the X direction is located in the positive direction of the X direction from the median line MM′.

The gate region 30 includes a first gate insulating film 31a, a first gate electrode 32a, a second gate insulating film 31b, and a second gate electrode 32b. The first gate electrode 32a is covered with the first gate insulating film 31a. The second gate electrode 32b is covered with the second gate insulating film 31b. The first gate insulating film 31a and the second gate insulating film 31b are formed to be spaced apart from each other in the X direction.

The third semiconductor region 23 includes a region close to the first gate insulating film 31a and a region close to the second gate insulating film 31b.

That is, when comparing a distance in the X direction between the third semiconductor region 23 and the first gate insulating film 31a with a distance in the X direction between the third semiconductor region 23 and the second gate electrode 32b, there are a region where the former is shorter than the latter and a region where the former is longer than the latter among the third semiconductor regions 23.

In this manner, a plurality of plugs 40 are provided in the Y direction to be electrically connected to the third semiconductor regions 23 that are disposed to be displaced from each other in the X direction. Positions of the plurality of third semiconductor regions are offset in the second direction (in the X direction). Positions of the plurality of plugs are also offset in the second direction (in the X direction).

A length L1 of the plug 40 in the X direction is different from a length L2 in the Y direction. For example, L1<L2, and L1≤2Tmax. In order to improve flatness and fill the plugs 40 more satisfactorily by preventing generation of voids, it is preferable that L1≤(5/3) Tmax or less. More preferably, L1≤(4/3) Tmax or less.

FIG. 8A is a cross-sectional view taken along a line E-E′ shown in FIG. 7. The third semiconductor region 23 is located near one of the gate regions 30 in the X direction. In other words, a distance between the third semiconductor region 23 and the first gate insulating film 31a is shorter than a distance between the third semiconductor region 23 and the second gate insulating film 31b.

The plug 40 is provided to penetrate an interlayer insulating film 50, and electrically connects a first electrode 11 and the semiconductor substrate 20. The plug 40 may be covered with a barrier metal 41. The barrier metal 41 has a layered structure containing, for example, Ti and TiN.

FIG. 8A shows an example in which the plug 40 is formed on the third semiconductor region 23 near the center of the third semiconductor region 23. On the other hand, the plug 40 may penetrate the third semiconductor region 23 in the Z direction and reach a second semiconductor region 22. In addition, the plug 40 is not limited to being formed near the center of the third semiconductor region 23 in the X direction, but may be formed at a position closer to or farther from the first gate insulating film 31a.

FIG. 8B is a cross-sectional view taken along a line F-F′ shown in FIG. 7. The third semiconductor region 23 is located in the X direction near the gate region 30 on a side in the X direction opposite to that in the case of FIG. 8A. A distance between the third semiconductor region 23 and the first gate insulating film 31a is longer than a distance between the third semiconductor region 23 and the second gate insulating film 31b.

The semiconductor substrate 20 and the first electrode 11 are electrically connected to each other via the plug 40.

In the semiconductor device 2 of this embodiment, the plug 40 is disposed in accordance with the arrangement of the third semiconductor region 23, and thus electrical connection between the third semiconductor region 23 and the plug 40 and electrical connection between the semiconductor substrate 20 and the first electrode 11 are improved.

First, description will be given by making a comparison with a case where electrical connection with the third semiconductor region 23 is attempted using a single plug 140 extending in the Y direction, as in the semiconductor device 102 of the second reference example shown in FIG. 6. With the single plug 140 shown in FIG. 6, when the third semiconductor region 23 is offset in the positive or negative direction of the X direction, there is a concern that a contact area between the plug 140 and the third semiconductor region 23 may be reduced. Furthermore, there is a concern that the electrical connection between the plug 140 and the third semiconductor region 23 may not be made at least partially.

Furthermore, as shown in FIG. 7, when the third semiconductor region 23 includes portions that are offset in the positive and negative directions of the X direction, there is a concern that a contact with the third semiconductor region 23 may not be sufficiently made using a single plug 140 as shown in FIG. 6. That is, when the plug 140 is formed to make a contact with the third semiconductor region 23 that is offset in one direction, it is difficult to make a contact with the third semiconductor region 23 that is offset in the other direction.

On the other hand, with the semiconductor device 2 of this embodiment shown in FIG. 7, the arrangement of each of the plurality of plugs 40 can be adjusted in the X direction, making it possible to form the plugs 40 above each of the third semiconductor regions 23 that are offset in the X direction. Thus, it is possible to secure a reliable contact between the plug 40 and the third semiconductor region 23.

For example, in FIG. 8A, a case where a first semiconductor region 21 is an n-type drift layer, the second semiconductor region 22 is a p⁻-type base layer, and the third semiconductor region 23 is an n⁺-type emitter layer is considered. By applying a positive voltage to the gate electrode 32 with respect to the first electrode 11, an n-type inversion layer is generated in the second semiconductor region 22, and the semiconductor device 2 is set to be in an ON state. FIG. 8A shows a structure in which the third semiconductor region 23 is located near the first gate electrode 32a among the plurality of gate electrodes 32. Thus, a current flowing in an ON state flows from the first semiconductor region 21 through the inversion layer generated mainly around the first gate insulating film 31a to the third semiconductor region 23.

The current flowing to the third semiconductor region 23 flows to the first electrode 11, which is, for example, an emitter electrode, via the plug 40 electrically connected to the third semiconductor region 23. In this embodiment, the plug 40 is disposed close to one gate region 30 (the first gate insulating film 31a and the first gate electrode 32a) in FIG. 8A in accordance with the arrangement of the third semiconductor region 23. It is possible to secure a more reliable electrical connection between the third semiconductor region 23 and the plug 40 than when the plug 40 is disposed close to the gate region 30 (the second gate insulating film 31b and the second gate electrode 32b) where the third semiconductor region 23 is not closely located in FIG. 8A.

The same is true of the arrangement of the third semiconductor region 23 and the plug 40 shown in FIG. 8B.

In this manner, the plug 40 is provided in accordance with the arrangement of the third semiconductor region 23, and thus with the semiconductor device 2 of this embodiment, it is possible to improve electrical connection between the semiconductor substrate 20 and the first electrode 11 via the plug 40. That is, with the semiconductor device 2 of this embodiment, the degree of freedom in designing the semiconductor device can be improved by diversifying a possible structure of the third semiconductor region 23. For a predetermined layout of the third semiconductor region 23, it is possible to expand the range of selection according to optimization of current control, including the arrangement of the plug 40 offset in the X direction between the gate regions 30. It is possible to further improve the electrical characteristics by appropriately selecting the layouts of the third semiconductor region 23 and the plug 40.

### Third Embodiment

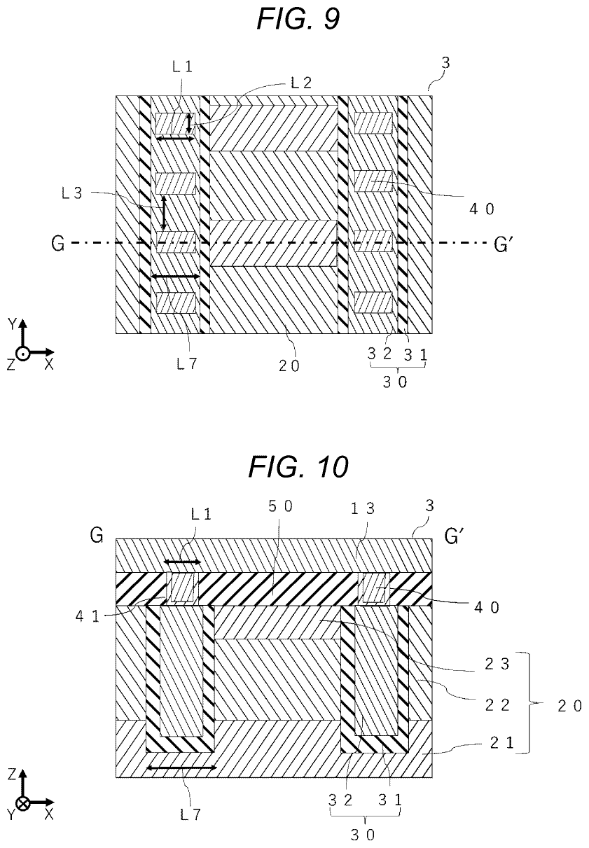

FIGS. 9 and 10 are an enlarged plan view and a cross-sectional view showing a semiconductor device 3 according to a third embodiment. FIG. 10 is a cross-sectional view showing a G-G′ cross section of the semiconductor device shown in FIG. 9. Description of portions in common with those in the first embodiment will be omitted as appropriate, and differences will be described.

In the semiconductor device 3 according to this embodiment, a gate electrode 32 provided in a gate region 30 is electrically connected to a plug 40. In FIG. 9, a plurality of plugs 40 are provided in the Y direction for the gate region 30 extending in the Y direction. In FIG. 9, a gate wiring 13 and an interlayer insulating film 50 shown in FIG. 10 are omitted.

As shown in FIG. 9, the plug 40 has a length L1 in the X direction and a length L2 in the Y direction. L1 is smaller than a length L7 of the gate electrode 32 in the X direction. In addition, for example, L2<L7, and the gate region 30 is wider in the X direction. An interval in the Y direction between the plurality of plugs 40 formed in the Y direction is L3. For example, L2<L1.

The plug 40 is electrically insulated from a semiconductor substrate 20 by a gate insulating film 31.

FIG. 10 is a cross-sectional view taken along a line G-G′ in FIG. 9. As shown in FIG. 10, the gate wiring 13 is electrically connected to the gate electrode 32 via the plug 40. The plug 40 is made of a metal containing, for example, W (tungsten). The gate electrode 32 contains, for example, polysilicon. The gate electrode 32 is, for example, a gate electrode of an IGBT, and the gate wiring 13 is, for example, a gate wiring electrically connected to the gate electrode 32. The potential of the gate electrode 32 can be controlled by applying a voltage to the gate wiring 13.

The plug 40 may be covered with a barrier metal 41. The barrier metal 41 has a layered structure containing, for example, Ti and TiN.

The semiconductor device 3 according to this embodiment may include a first electrode 11 provided on the interlayer insulating film 50 in a region separated from the region shown in FIGS. 9 and 10. The first electrode 11 is, for example, an emitter electrode of an IGBT. The first electrode 11 is electrically connected to a third semiconductor region 23 of the semiconductor substrate 20 via a conductive member (not shown) provided in the interlayer insulating film 50. The third semiconductor region 23 is, for example, an emitter region of an IGBT.

Furthermore, the conductive member connecting the first electrode 11 and the semiconductor substrate 20 may be a plug 40 different from the plugs 40 shown in FIGS. 9 and 10. In other words, a plug 40 different from the plugs 40 shown in the drawings may electrically connect the semiconductor substrate 20 and the first electrode 11 not shown in FIG. 9. The semiconductor device 3 according to this embodiment may have a structure as shown in FIGS. 1B and 2A in a region not shown in FIG. 9.

That is, the potentials of the semiconductor substrate 20 and the gate electrode 32 may be controlled via a plurality of plugs 40. That is, by a structure not shown in FIGS. 9 and 10, it is possible to control the potential of the semiconductor substrate 20 via the plugs 40 and separately control the potentials of the emitter electrode of the IGBT and the gate electrode via different plugs 40.

With the semiconductor device 3 of this embodiment, the plurality of plugs 40 are spaced apart from each other in the Y direction, and thus it is possible to improve electrical connection between the gate wiring 13 and the gate electrode 32 regardless of the value of L7. For various shapes of the gate electrode 32, it is possible to improve electrical connection by the plugs 40 and reliably form an inversion layer in the semiconductor substrate 20.

Furthermore, a shorter length out of L1 and L2 is set to, for example, 2Tmax or less, and thus it is possible to prevent defective formation of the plugs 40 while preventing wafer warpage. It is possible to improve the reliability of the semiconductor device by preventing defective formation.

With the semiconductor device 3 of this embodiment, it is possible to form a plug 40 having a length L1 that is proportional to L7. As L7 increases, it is possible to increase a contact area between the gate electrode 32 and the plug 40.

In addition, L7 may be within the range of an inequality n×2Tmax+ (n−1)×Lmin<L7< (2n+1)× Lmin for a certain natural number n.

By increasing the range of selection of the value of L7, it is possible to increase the range of selection according to optimization of current control, for example, when the magnitude and distribution of a current flowing through the semiconductor device are controlled in accordance with the arrangement of the gate region 30. It is possible to improve the electrical characteristics by appropriately selecting the value of L7.

Furthermore, it is possible to control the potential of the gate electrode 32 by electrically connecting the gate electrode 32 and the gate wiring 13 via the plug 40. The potentials of the plurality of gate electrodes 32 arranged in the X direction can be individually controlled by different plugs 40, and a multi-gate structure can be achieved by the plurality of plugs 40. By individually controlling the potentials of the gate electrodes 32, it is possible to reduce a loss during switching and further improve the performance of the semiconductor device.

In at least one embodiment described above, the plurality of plugs 40 provided in the Y direction each have a length L1 in the X direction and a length L2 in the Y direction, and at least one of L1 and L2 is formed short to be able to reduce stress on a wafer. Thus, a contact area between the plugs 40 and the semiconductor substrate 20 is made large by forming the other of L1 and L2 long, and thus it is possible to improve the performance of the semiconductor device for a wider range of the value of LG or L7. In addition, it is possible to prevent defective formation of the plugs 40 and improve the reliability of the semiconductor device.

In addition, it is possible to improve the degree of freedom in design for the range of the value of LG or L7 and improve the degree of freedom in design for the layouts of the third semiconductor region 23 and the plug 40. It is possible to increase the range of selection of the value of LG or L7 or the layouts of the third semiconductor region 23 and the plug 40. By appropriately selecting the value of LG or L7 or the layouts of the third semiconductor region 23 and the plug 40, the electrical characteristics of the semiconductor device can be improved by optimizing current control.

Hereinafter, a manufacturing method for a semiconductor device will be described.

A manufacturing method for the semiconductor device 1 according to the first embodiment will be described with reference to FIGS. 11 to 16.

In the following description, FIGS. 11 to 16 are cross-sectional views corresponding to the A-A′ cross section of the semiconductor device shown in FIG. 1B. That is, FIGS. 11 to 16 show cross-sectional views at positions corresponding to the A-A′ cross section of the semiconductor device shown in FIG. 1B, which is a completed diagram, in the respective manufacturing processes.

In description of the manufacturing method, the formation of the plug 40 will be described in detail, while description of the formation of the gate region 30, the semiconductor substrate 20, and the second electrode 12 will be omitted since it is not significantly different from a general manufacturing method.

FIG. 11 is a cross-sectional view showing a process of providing the interlayer insulating film 50. The semiconductor device 1 includes the semiconductor substrate 20 and the gate region 30 for which the manufacturing method is not described. The semiconductor substrate 20 contains, for example, Si, and an n-type semiconductor layer is formed, for example, by doping with N or P, and the p-type semiconductor layer is formed, for example, by doping with B. The gate region 30 includes the gate insulating film 31 and the gate electrode 32. The gate insulating film 31 contains, for example, silicon oxide. The gate electrode 32 is, for example, polysilicon.

As shown in FIG. 11, the interlayer insulating film 50 is provided on the semiconductor substrate 20 and the gate region 30. The interlayer insulating film 50 is, for example, an oxide film containing silicon oxide which is formed by chemical vapor deposition (CVD).

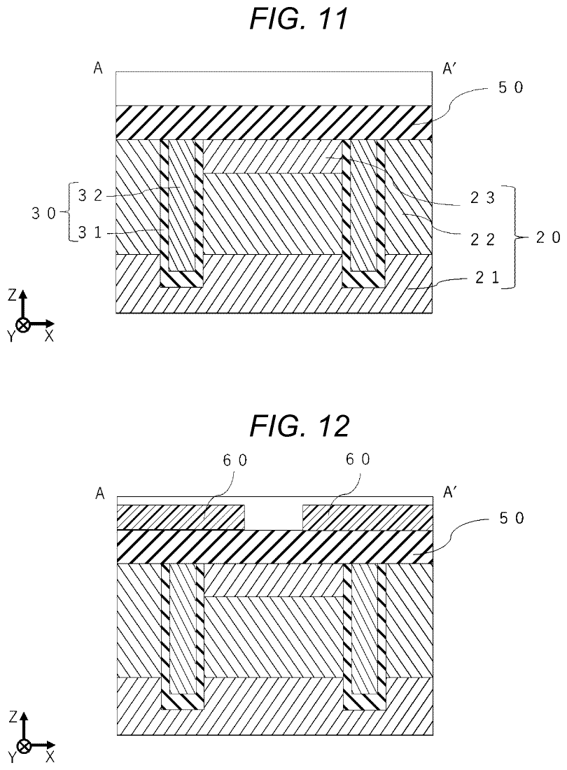

Next, as shown in FIG. 12, a resist 60 is provided on the interlayer insulating film 50. The resist 60 is selectively formed, for example, by photolithography.

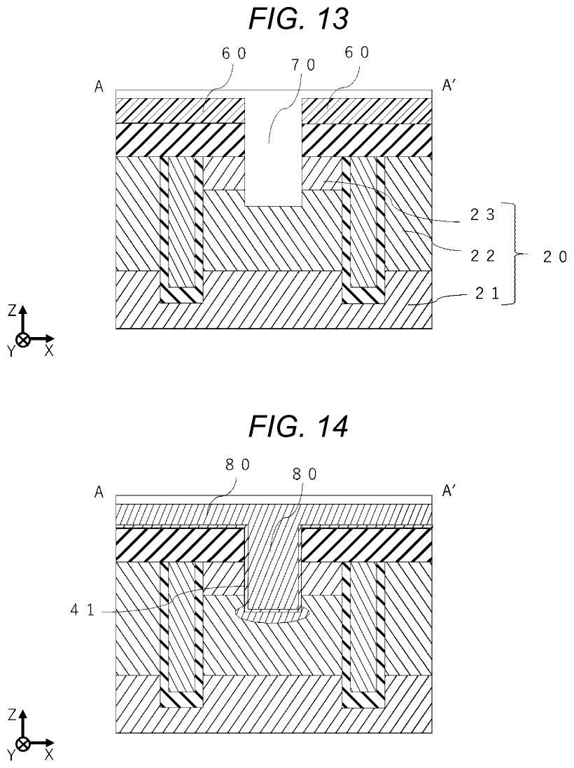

Next, as shown in FIG. 13, an opening 70 is provided by excavating a portion where the resist 60 is not provided. A plurality of openings 70 are formed at intervals in the Y direction. The openings 70 are formed by, for example, reactive ion etching (RIE) or chemical dry etching (CDE). Some of the plurality of openings 70 penetrate the third semiconductor region 23 as shown in FIG. 13 and reach the second semiconductor region 22. Some of them may also reach the second semiconductor region 22 without being in contact with the third semiconductor region 23 in a cross section different from the A-A′ cross section shown in FIG. 13.

Next, the resist 60 is peeled off, and a conductive film 80 is formed as shown in FIG. 14. However, the barrier metal 41 may be formed before the conductive film 80 is formed. The barrier metal 41 has a layered structure containing, for example, Ti and TiN. The barrier metal 41 is formed by, for example, CVD. The conductive film 80 contains, for example, W (tungsten). The conductive film 80 is formed by, for example, CVD.

Next, as shown in FIG. 15, the conductive film 80 is partially removed by etching back, and the remaining part is referred to as a plug 40.

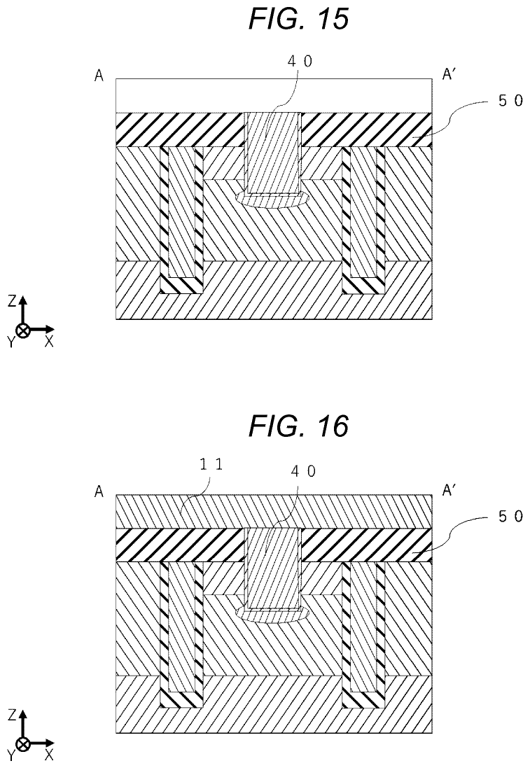

Finally, as shown in FIG. 16, the first electrode 11 is provided on the plug 40 and the interlayer insulating film 50. The first electrode 11 contains, for example, AlCu or AlSi. The first electrode 11 is formed by, for example, sputtering. In this manner, the configuration shown in FIG. 2A is obtained.

In the manufacturing method described above, in the process of embedding the conductive film 80 in the opening 70 to form the plug 40, for example, as described for the semiconductor device 1 according to the first embodiment, a plurality of plugs 40 are provided in the Y direction, and thus a contact area between the plug 40 and the semiconductor substrate 20 can be increased over a wider range of the value of an interval (LG shown in FIG. 1B) between the gate regions 30. Further, in the process of embedding the conductive film 80 in the opening 70 to form the plug 40, the opening 70 has, for example, a rectangular shape in the XY plane, and thus it is possible to prevent generation of voids to achieve satisfactory embedding while reducing stress applied to the semiconductor substrate 20 by the plug 40.

The embodiments are described above with reference to the specific examples. However, the embodiments are not limited to the specific examples. That is, the specific examples in which the designs are changed by a person skilled in the art are also included in the embodiments as long as they have the characteristics of the embodiments. The elements of the above-described specific examples, their arrangements, materials, conditions, shapes, sizes and the like are not limited to illustrated ones and may be appropriately changed.

In addition, the elements of the above-described embodiments can be combined if technically possible, and the combined elements are included in the scope of the embodiments as long as they have the characteristics of the embodiments. It is understood that variations and modifications can be made by a person skilled in the art within the scope of the idea of the embodiments, and the variations and modifications are also included in the scope of the embodiments.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor substrate;
an interlayer insulating film that is provided on the semiconductor substrate;
a first electrode that is provided on the interlayer insulating film;
a second electrode that is provided below the semiconductor substrate;
a plurality of gate regions extending from the interlayer insulating film in a first direction, which is a thickness direction of the semiconductor substrate, to reach the semiconductor substrate, provided in a second direction intersecting the first direction, and extending in a third direction intersecting the first direction and the second direction; and
a plurality of plugs located between the gate regions in the second direction, longer in the second direction than in the third direction, spaced apart from each other in the third direction, and electrically connecting the first electrode to the semiconductor substrate.

2. The semiconductor device according to claim 1, wherein a shape of each of the plugs in a plane including the second direction and the third direction is a rectangular or elliptical shape.

3. The semiconductor device according to claim 2, wherein
the semiconductor substrate includes
a first semiconductor region of a first conductivity type,
a second semiconductor region of a second conductivity type which is provided on the first semiconductor region,
a third semiconductor region of the first conductivity type which is selectively provided on the second semiconductor region, and
a fourth semiconductor region of the second conductivity type which is provided between the second electrode and the first semiconductor region, and
the gate region includes
a gate electrode that is embedded in the gate region, and
a gate insulating film that covers the gate electrode.

4. The semiconductor device according to claim 3, wherein the third semiconductor region includes a plurality of sub-regions, which are provided between a plurality of the gate regions and spaced apart from each other in the third direction.

5. The semiconductor device according to claim 4, wherein at least one of the plugs is in contact with the second semiconductor region and is provided between two of the sub-regions of the third semiconductor region.

6. The semiconductor device according to claim 5, wherein at least some of the plurality of plugs that are provided adjacent to each other in the third direction, are in contact with the third semiconductor region.

7. The semiconductor device according to claim 5, wherein at least some of the plurality of plugs that are provided adjacent to each other in the third direction, are each located between two of the sub-regions of the third semiconductor region.

8. The semiconductor device according to claim 1, wherein a depth D of each of the plugs in the first direction and a length L1 of each of the plugs in the second direction satisfy the relationship: 0<D/L1≤2.

9. The semiconductor device according to claim 1, wherein each of the plugs contains W.

10. The semiconductor device according to claim 9, wherein the semiconductor device further comprises a barrier metal that covers each of the plugs and contains Ti and TiN.

11. A semiconductor device comprising:
a semiconductor substrate;
an interlayer insulating film that is provided on the semiconductor substrate;
a first electrode that is provided on the interlayer insulating film;
a second electrode that is provided below the semiconductor substrate;
a plurality of gate regions extending from the interlayer insulating film in a first direction, which is a thickness direction of the semiconductor substrate, to reach the semiconductor substrate, provided in a second direction intersecting the first direction, and extending in a third direction intersecting the first direction and the second direction; and
a plurality of plugs located between the gate regions in the second direction, spaced apart from each other in the third direction, and electrically connecting the first electrode to the semiconductor substrate; and
a plurality of third semiconductor regions in the semiconductor substrate, provided between a plurality of the gate regions, and not aligned in the third direction.

12. The semiconductor device according to claim 11, wherein the third semiconductor regions are spaced apart from each other in the third direction.

13. The semiconductor device according to claim 11, wherein positions of the plurality of third semiconductor regions are offset in the second direction.

14. The semiconductor device according to claim 13, wherein positions of the plurality of plugs are offset in the second direction.

15. The semiconductor device according to claim 11, wherein some of the third semiconductor region are located on a first side of a line extending in the third direction, and some of the third semiconductor regions are located on a second side of the line that is opposite to the first side.

16. The semiconductor device according to claim 11, wherein
one of the plurality of the gate regions includes a first gate insulating film and a second gate insulating film spaced apart from the first gate insulating film in the second direction, and
some of the third semiconductor regions are closer to the first gate insulating film than the second gate insulating film, and
some of the plurality of plugs are closer to the first gate insulating film than the second gate insulating film.

17. The semiconductor device according to claim 11, wherein each of the plugs contains W.

18. A semiconductor device comprising:
a semiconductor substrate;
an interlayer insulating film that is provided on the semiconductor substrate;
a first electrode that is provided on the interlayer insulating film and is connected to the semiconductor substrate;
a gate wiring that is provided on the interlayer insulating film to be spaced apart from the first electrode;
a second electrode that is provided below the semiconductor substrate;
a plurality of gate regions extending from the interlayer insulating film in a first direction, which is a thickness direction of the semiconductor substrate, to reach the semiconductor substrate, provided in a second direction intersecting the first direction, and extending in a third direction intersecting the first direction and the second direction, each of the gate regions including a gate electrode that is embedded in the gate region and a gate insulating film that covers the gate electrode; and
a plurality of plugs that are spaced apart from each other in the third direction and electrically connect the gate wiring to the gate electrode of each of the gate regions.

19. The semiconductor device according to claim 18, wherein the plugs are longer in the second direction than in the third direction.

20. The semiconductor device according to claim 18, wherein each of the plugs contains W.
